(19) United States
(12) Patent Application Publication
(10) Pub. No.: US 2017/0330743 A1
(43) Pub. Date: Nov. 16, 2017

(54) DIELECTRIC BARRIER LAYER

(71) Applicant: THE UNIVERSITY OF LIVERPOOL, Liverpool (GB)

(72) Inventors: Paul R. CHALKER, Liverpool (GB); Joseph William ROBERTS, Liverpool (GB)

(21) Appl. No.: 15/527,198

(22) PCT Filed: Nov. 17, 2015
(86) PCT No.: PCT/GB2015/053488

§ 371 Date: May 16, 2017

(30) Foreign Application Priority Data
Nov. 17, 2014 (GB) 1420366.5

(51) Int. Cl. H01L 21/02; H01L 29/51

(52) U.S. Cl. CPC H01L 21/0228; H01L 29/517; H01L 21/02178; H01L 29/513

(57) ABSTRACT

The present invention relates to a method of forming a fluorine-doped metal oxide dielectric layer suitable for forming a dielectric barrier layer in an integrated circuit device. The method comprises the deposition of a plurality of layers of oxide dielectric onto a substrate by a plurality of cycles of atomic layer deposition, wherein one or more of said cycles of atomic layer deposition additionally comprises the atomic layer deposition of fluorine. In addition, the present invention relates to the dielectric films formed by this methodology and to integrated electronic devices that comprise these metal oxide dielectric barrier layers.

### FIELD OF THE INVENTION

The present invention relates to gate dielectric layers that are component parts of certain integrated circuit devices, especially high voltage operation transistors and capacitors, for example gallium nitride-based field effect transistors (FETs), high electron mobility transistors (HEMTs) and metal-organic-semiconductor (MOS) capacitors. In particular, the present invention relates to a method of making a dielectric layer as well as to the dielectric films formed by this methodology and to integrated electronic devices that comprise these dielectric barrier layers.

### BACKGROUND OF THE INVENTION

Gallium nitride-based field effect transistors (FET) are currently under development for high-power switching device applications. The GaN-based materials are being exploited due to their high voltage electrical breakdown and high thermal conductivities. In addition, in heterostructure FET (HFET) devices, high electron mobilities are achievable at the AlGaN/GaN hetero-interface.

To reduce gate leakage currents, a range of so-called high-k materials (κ>3.9 the permittivity of SiO₂) including Al₂O₃, HfO₂ and ZrO₂ have been investigated as gate dielectric barrier layers in the AlGaN/GaN metal-oxide-semiconductor HFETs (MOSHFET). Al₂O₃ has been extensively studied because of its well-established processing route via atomic layer deposition (ALD) and because the dielectric constant (K=7-8) and large conduction band offset relative to GaN (2.2 eV) [7], are effective in reducing the gate leakage and drain current collapse.

ALD is a process that uses alternate doses of precursors, which chemisorb onto the substrate surface. Surface reactions between the reagent pulses eliminates unwanted by-products and the film deposition progresses stepwise to build up the target material. The reactor is purged with an inert gas between the precursor pulses to suppress unwanted gas phase or pre-reactions and, with appropriate adjustment of the experimental conditions, the process proceeds via saturative steps. The ALD of Al₂O₃ is one of the most widely studied and commonly uses a combination of trimethyl aluminium (TMA) either with water vapor, oxygen plasma or ozone as oxidizing co-reagents, to form alumina.

However, the benefits of Al₂O₃ are somewhat mitigated by reduced transconductance [A1] and an accompanying threshold voltage shift [A2]. In particular, the oxide gate dielectric layers formed from Al₂O₃ have issues which include adverse interface state density (Dᵢₜ) and trapped charge within the insulator. These effects influence the transistor threshold voltage (Vₜₕ) and the two-dimensional electron gas (2DEG) characteristics of the device channel.

There is therefore a need for methodologies for overcoming one or more of the aforementioned disadvantages associated with Al₂O₃ gate dielectric layers.

Fluorine-doped alumina gate dielectric (Al₂O₃:F) layers are exploited in gallium nitride (GaN)-based power electronics to enable high voltage operation with low off-state electrical leakage. The incorporation of fluorine (F) counteracts the native oxide traps and increases the threshold voltage of the alumina dielectric layer, thereby enabling the fabrication of enhancement mode or normally ‘off’ transistors.

Various fluorine treatments have been investigated previously as a means of ameliorating the electrical charge issues associated with Al₂O₃ gate dielectric layers in gallium nitride integrated circuit device structures. A fluorine-based plasma treatment has been previously described as a method of incorporating negatively charged fluorine (F) ions into the AlGaN barrier of an E-mode HEMT and resulted in a positive shift in the threshold voltage, although the performances of the devices were reported as modest [A5].

The same group subsequently developed normally off AlGaN/GaN MISHEMT devices by exploiting fluorinated Al₂O₃ thin film gate dielectrics, prepared using the fluorine-based plasma treatment. The E-mode MISHEMTs exhibited high transconductance and large saturated drain currents when the plasma treatment was performed on the dielectric surface [A6]. It was reported that the F-distribution was confined to the top 2 nm of the dielectric and furthermore avoided plasma-induced damage at the interface with the Group III-nitride. Zhang et al [A7] have reported the compensation of the intrinsic positive charges in Al₂O₃ gate dielectric by fluorine ions incorporated into the Al_{0.26}Ga_{0.74}N barrier of a GaN metal-oxide-semiconductor high-electron-mobility transistors (MOSHEMTs) by CF₄ plasma treatment. The incorporated fluorine redistributed by diffusion back into the Al₂O₃ during the atomic layer deposition at 250° C., although a further post-deposition anneal at 400° C. left the F distribution almost unchanged. The capacitance-voltage (CV) characteristics of a 20 nm thick F-treated Al₂O₃ film in a MOS diode showed a 60-70% increase in capacitance (f=1 kHz) compared with an untreated film.

An object of the present invention is therefore the provision of an improved process for forming fluorine-doped alumina dielectric layers/films for use in gallium nitride-based integrated circuit devices.

### SUMMARY OF THE INVENTION

The present invention relates to the development of an improved atomic layer deposition (ALD) process to deposit fluorine-doped metal oxide dielectric layers (e.g. alumina (Al₂O₃), hafnia (HfO₂), zirconia (ZrO₂) or similar), which form gate dielectric barrier layers in integrated circuit devices.

The present invention therefore provides a method of forming a fluorine-doped metal oxide dielectric layer suitable for forming a dielectric barrier layer in an integrated circuit device, the method comprising the deposition of a plurality of layers of metal oxide onto a substrate by a plurality of cycles of atomic layer deposition, wherein one or more of said cycles of atomic layer deposition additionally comprises the atomic layer deposition of fluorine.

The introduction of fluorine into one or more cycles of the atomic layer deposition enables a desired proportion of fluorine to be incorporated into the metal oxide dielectric layer as it forms, i.e. the fluorine is effectively added in situ as the metal oxide dielectric layer is formed.

The ability to incorporate the fluorine into the metal oxide dielectric layer in this manner confers a number of advantages.

Firstly, the method of the present invention avoids the need for separate plasma treatments to introduce fluorine to the barrier layer, which can be detrimental to the underlying substrate layer in certain circumstances; thereby reducing the number of processing steps needed to introduce fluorine. Secondly, the methodology of the present invention enables the amount of fluorine required to be significantly reduced in barrier layer as a whole. Furthermore, the required ratio of fluorine:metal oxide can be attained by controlling the number of atomic layer deposition steps during which fluorine is introduced and/or the amount of fluorine used in each deposition. Lastly, the distribution of fluorine throughout the dielectric layer can be controlled by selecting when to introduce the fluorine during the formation of the metal oxide layer and/or by varying the amount introduced at each stage [for example, it may be introduced in a uniform manner throughout the layer (e.g. by introducing fluorine dopant in 1 out of every 11 atomic layer deposition cycles) or it may be non-uniform (e.g. with larger amounts of fluorine introduced at certain positions within the layer such as proximate to the surfaces of the layer)].

The incorporation of fluorine in this manner also results in a metal oxide gate dielectric layer with reduced bulk metal oxide charge, which is observed in the reduced capacitance-voltage hysteresis of the layer. In the example section herein, the methodology of the present invention is used to prepare a fluorine-doped alumina barrier layer by the atomic layer deposition of Al₂O₃ on GaN-on-silicon substrates, which are then used to fabricate metal-oxide-semiconductor (MOS) capacitors and transistors. As demonstrated in the accompanying examples, the current-voltage (I-V) characteristics of the fluorine-doped alumina (Al₂O₃:F) exhibited low leakage current densities of 10⁻⁹ Acm⁻².

Thus, the methodology of the present invention also (i) enhances the dielectric properties and induces positive threshold voltages in the metal oxide dielectric layer; (ii) reduces the native bulk charge in the metal oxide dielectric layer, in order to achieve reduced leakage current and hysteresis; and (iii) reduces the interface states at the interface between the metal oxide dielectric and the substrate, e.g. gallium nitride.

In a further aspect, the present invention provides a fluorine-doped metal oxide dielectric layer obtainable by, obtained by or directly obtained by the methodology defined herein.

In another aspect, the present invention provides an integrated circuit device comprising a fluorine-doped metal oxide dielectric layer according to the present invention.

Suitably, the integrated circuit device is a transistor or capacitor, for example a field effect transistor (FET), high electron mobility transistors (HEMTs) or metal-oxide-semiconductor capacitors.

### DETAILED DESCRIPTION OF THE INVENTION

### Methods of Forming Fluorine-Doped Metal Oxide Dielectric Layers by Atomic Layer Deposition

As previously indicated, the present invention provides a method of forming a fluorine-doped metal oxide dielectric layer suitable for forming a dielectric barrier layer in an integrated circuit device, the method comprising the deposition of a plurality of layers of metal oxide onto a substrate by a plurality of cycles of atomic layer deposition, wherein one or more of said cycles of atomic layer deposition additionally comprises the atomic layer deposition of fluorine.

The method involves depositing a plurality of layers of metal oxide onto the surface of a substrate by atomic layer deposition.

The substrate may be any suitable substrate used in the fabrication of integrated circuit devices, such as, for example, field effect transistors (FETs) and high electron mobility transistors (HEMTs). The substrate layer is usually the preceding layer formed in the preparation of transistor or capacitor stack. Typically, this layer will be a gallium nitride (GaN) layer, AlN, AlGaN layer, AlInN layer or similar substrate layers known in the art (e.g. a nitride based alloy in which a two dimensional electron/hole gas can be formed as a channel).

The metal oxide layer may be any suitable metal oxide dielectric material known in the art. For example, the metal oxide may be alumina (Al₂O₃), hafnia (HfO₂), zirconia (ZrO₂) or similar [e.g. rare earth element (RE) oxides (RE₂O₃ or REO₂)], or mixtures thereof. The metal oxide layer may be either in the pure state or in a doped state. The metal oxide layer may further comprise ternary or quarternary compositions of the metal oxide dielectric which are either in a pure or doped compositional state.

In an embodiment, the metal oxide is selected from alumina (Al₂O₃), hafnia (HfO₂), or zirconia (ZrO₂). In a particular embodiment, the metal oxide is alumina.

Suitable techniques for the atomic layer deposition of metal oxide onto the substrate are known in the art. The layer is grown by successive cycles of deposition, each cycle depositing a layer of the metal oxide.

In embodiments where the metal oxide layer is alumina, each cycle typically comprises the atomic layer deposition of an aluminium source, which is typically an organo-aluminium compound (e.g. trimethyl aluminium or another aluminium precursor suitable for the atomic layer deposition (ALD) of alumina), followed by the deposition of water vapour, oxygen plasma treatment or ozone. The water vapour, oxygen plasma treatment or ozone react with the trimethyl aluminium at the substrate surface to form a layer of alumina.

The cycle can be repeated to lay down successive layers of metal oxide until a metal oxide dielectric layer of the desired thickness is obtained. Typically, the thickness of the metal oxide dielectric layer is from 1 nm to 500 nm.

The total number of cycles of atomic layer depositions may be within the range of 5 to 100,000 cycles. More preferably, the total number of cycles is within the range of 50 to 2000 cycles. In an embodiment, the total number of cycles is within the range of 500 to 1500 cycles.

The methodology of the present invention further requires that one or more of the cycles for depositing one or more layers of oxide further comprises the atomic layer deposition of fluorine.

The atomic layer deposition of fluorine can be facilitated by introducing a predetermined amount of suitable fluorine source into the ALD apparatus. Suitably, the fluorine is introduced alternating between doses of the metal oxide source.

It is possible to introduce some fluorine with every cycle should that be desired (i.e. 100% doping). Alternatively, the fluorine may be introduced in just a proportion of the cycles.

Furthermore, the fluorine can be introduced at a regular intervals during the process (e.g. in every cycle or at rate of one deposition of fluorine in every 2 to 25 cycles of metal oxide deposition) so as to provide a regular distribution of fluorine throughout the metal oxide dielectric layer or, alternatively, it may be introduced in an irregular manner to provide a more varied distribution throughout the dielectric barrier layer should this be desired.

Any suitable fluorine source that is compatible with ALD processes may be used. Examples of possible fluorine sources include fluorocarbons that are miscible with water or other suitable solvent, xenon fluoride, or an aqueous fluoride solution (especially an aqueous ammonium fluoride solution).

In a particular embodiment, the fluoride source is an aqueous solution of ammonium fluoride, which is introduced into the ALD apparatus as a vapour and forms a deposit of fluorine on the substrate surface and ammonia as a by-product, which is easily removed by purging the deposition chamber of the ALD apparatus with an inert gas. The ammonium fluoride solution can be substituted for the water vapour deposition step in one or more of the metal oxide deposition cycles.

In addition to the frequency at which fluorine is introduced, the amount of fluorine introduced at any time can be varied by varying the concentration of the ammonium fluoride in the solution and/or the amount of ammonium fluoride vapour injected into the deposition chamber of the ALD apparatus.

In some instances, it may be desirable to include a co-dopant with the fluorine. The co-dopant may serve to hold the fluorine in place within the metal oxide layer by the formation of a complex with the fluorine. Illustrative examples of suitable co-dopants include nitrogen (N—F or nitrogen-fluorine), boron (B—F or boron-fluorine) or phosphorus (P—F or phosphorus-fluorine).

The nitrogen co-dopant may be introduced by ALD of aqueous NH₄OH and NH₄F. The boron co-dopant may be introduced by ALD of aqueous BH₃NH₃ and NH₄F. The phosphorus co-dopant may be introduced by ALD of aqueous H₃PO₄ and NH₄F.

The desired ratio of metal oxide:fluorine will vary depending on the precise properties desired in the dielectric barrier layer. In an embodiment, the amount of fluorine present in the metal oxide dielectric layer may vary from 0.1 ppm to 10 atomic percent.

In an embodiment, fluorine is introduced in one in every 1 to 200 cycles of metal oxide atomic layer deposition. In a further embodiment, fluorine is introduced in one in every 2 to 100 cycles of metal oxide atomic layer deposition. In another embodiment, fluorine is introduced in one in every 5 to 25 cycles of metal oxide atomic layer deposition. In a particular embodiment, fluorine is introduced in one in every 11 cycles of metal oxide atomic layer deposition.

In an embodiment, the method comprises the deposition of a plurality of layers of alumina onto a substrate by a plurality of cycles of atomic layer deposition in which an organo-aluminium compound (e.g. trimethyl aluminium) is deposited by atomic layer deposition followed by the deposition of water vapour, and in a proportion of these cycles, the water vapour deposition step is replaced with the introduction of an aqueous ammonium fluoride solution. In a particular embodiment, the aqueous ammonium fluoride solution is introduced in place of the water vapour deposition step in approximately one in every 1 to 30 cycles. In a further embodiment, the aqueous ammonium fluoride solution is introduced in place of the water vapour deposition step in approximately one in every 5 to 15 cycles.

Suitably, the method of the present invention is carried out at a substrate temperature of 185° C. to 300° C. Most suitably, the method of the present invention is carried out at a substrate temperature of 190° C. to 250° C.

Suitably, the pressure is within the deposition chamber of the ALD apparatus is within the range of 10 to 1000 mTorr. Most suitably, the pressure is 180 to 220 mTorr. In a particular embodiment, the pressure is 200 mTorr.

Suitably, the ALD apparatus has a number of injection ports to enable different components to be introduced into the deposition chamber. Suitably, the chamber is purged following each deposition step to ensure that no gas phase pre-reactions occur.

Suitably the chamber is purged with an inert gas, for example argon. The flow rate of inert gas (e.g. argon) is typically 50 to 150 std cm³ min⁻¹. In a particular embodiment, the flow rate of inert gas is 100 std cm³ min⁻¹.

Once formed, the fluorine-doped dielectric layer is suitably annealed by heating to 350° C. to 500° C.

Suitably, the process of the present invention allows for the incorporation of less than 10²² ions/cm³ of fluorine into the fluorine-doped metal oxide dielectric barrier layer. More suitably, the process of the present invention allows for the incorporation of less than 10²⁰ ions/cm³ of fluorine into the fluorine-doped metal oxide dielectric barrier layer. Yet more suitably, the process of the present invention allows for the incorporation of less than 10¹⁹ ions/cm³ of fluorine into the fluorine-doped metal oxide dielectric barrier layer. Most suitably, the process of the present invention allows for the incorporation of less than 10¹⁸ ions/cm³ of fluorine into the fluorine-doped metal oxide dielectric barrier layer.

It will be appreciated that the process of the present invention allows for the preparation of fluorine-doped metal oxide dielectric barrier layers that display a positive shift in threshold voltage.

Suitably, the process of the present invention allows for the preparation of fluorine-doped metal oxide dielectric barrier layers with a threshold voltage of >0V. More suitably, the process of the present invention allows for the preparation of fluorine-doped metal oxide dielectric barrier layers with a threshold voltage of >+2V. Most suitably, the process of the present invention allows for the preparation of fluorine-doped metal oxide dielectric barrier layers with a threshold voltage of >+5V.

### Fluorine-Doped Metal Oxide Dielectric Layer

In a further aspect, the present invention provides a fluorine-doped metal oxide dielectric barrier layer obtainable by, obtained by or directly obtained by the methodology defined herein.

In the methodology of the present invention, the fluorine-doped metal oxide dielectric layer is formed in situ as the metal oxide layer is formed. This provides a different distribution of fluorine within the metal oxide layer to that achievable using any of the prior art techniques for fluorine doping. It also enables fluorine-doped metal oxide dielectric layers to be formed that comprise significantly lower amounts of fluorine.

In another aspect, the present invention provides a fluorine-doped metal oxide dielectric barrier layer comprising an metal oxide and less than 10 at. % fluorine.

### Integrated Circuit Devices

In another aspect, the present invention provides an integrated circuit device comprising a fluorine-doped alumina dielectric layer according to the present invention.

Suitably, the integrated circuit device is a transistor, for example a field effect transistor (FET) and high electron mobility transistors (HEMTs), or a capacitor. Particular examples include HFETs and MOSHFETs and metal-oxide-semiconductor capacitors (MOS capacitors).

Such devices are well known in the art. For example, reference is made to the devices described in US2007/0205433, US2014/0145243 and A5, A6 and A7, all of which describe devices comprising dielectric barrier layers.

### BRIEF DESCRIPTION OF THE DRAWINGS

The invention is described further in reference to the accompanying Figures in which:

FIG. 1a shows a depth profile of the fluorine distribution in the 10% and 100% cycle doped films obtained using secondary ion mass spectrometry;

FIG. 1b shows a plot of n²−1 versus 1/λ² for spectroscopic ellipsometry measurements for films of undoped alumina and with doping cycle percentages of 10% and 100%;

FIGS. 1c and 1d show transmission electron micrographs recorded from cross sections of MOS capacitors fabricated from the Al₂O₃:F films;

FIG. 2 shows the following:

FIG. 2(a) Capacitance-voltage curves show F-addition shifts the threshold voltage and reduces the hysteresis caused by defects in the oxide

FIG. 2(b) dC/dV makes the positive flatband voltage due to F-addition much more apparent

FIG. 2(c) The leakage current (I-V) data shows leakage suppression although 10% seems to reinstate leakage again—suggesting upper limit to benefit from doping

FIG. 2(d) All samples benefit from forming gas annealing (FGA) at 430° C. for 30 minutes

FIGS. 3a to 3f show the transistor characteristic of drain current under conditions of Drain-Source (DS) and Gate-Source (GS) voltage bias.

### EXAMPLES

### Example 1—the In-Situ ALD Fluorine Doping Process

In the following description of the methodology of the present invention, it will be appreciated that the cyclic nature of the introduction of the organometallic and oxidant co-reagent (either H₂O or NH₄F/H₂O) means that the fluorine content of the dielectric can be controlled by varying the ratio of H₂O:NH₄F/H₂O cycles used.

The ALD Al₂O₃ dielectric films were deposited onto GaN on Si(111) wafers grown by Metal Organic Chemical Vapor Phase Deposition (MOCVD). The three precursors (SAFC Hitech) were trimethyl aluminium (TMA), deionised water and a 16% or 40% aqueous solution of ammonium fluoride.

The atomic layer deposition experiments were performed in an Oxford Instruments Plasma Technology OpAL Plasma ALD reactor incorporating a 200 mm diameter heater controllable between 25 and 500° C. The system is pumped by an oil filled rotary pump, capable of achieving a base pressure of approximately 20 mTorr. The liquid TMA, H₂O and 16% or 40% NH₃F/H₂O sources were delivered, at ambient temperature, into the process chamber from independent sources. The precursor delivery was achieved via vapour draw. The precursor delivery lines from the module to the process chamber are heated. Precursors are delivered into the chamber by fast ALD valves with a minimum opening time of 1 ms. Details of the ALD parameters employed are shown in table 1 below.

TABLE 1
ALD growth parameters

| | | |
|---|---|---|
| Substrate Temperature | 200° | C. |
| Pressure | 200 | mTorr |
| Argon flow | 100 | std cm³min⁻¹ |

| | |
|---|---|
| Pulse Sequences: | |
| TMA | [0.02 s dose/2 s purge] |
| H₂O | [0.3 s dose/2 purge] |
| 16% NH₃F/H₂0 | [0.3 s dose/2 s purge] |

The Al₂O₃:F films are deposited using x cycles of Al₂O₃ steps, via exposure of the surface to successive steps of TMA and then water vapour. Intermittent pump purge steps are used to prevent gas-phase pre-reaction, which ensures the surface reaction. After the x [Al₂O₃]cycles, a single Al₂O₃:F cycle is deposited, via exposure of the surface to successive steps of TMA and then ammonium fluoride solution. The whole process is repeated N times until the required film thickness is achieved. A typical growth run would use a Al₂O₃:F ratio of 10:1 whereby x=10 and N=100, giving a total number of 1000 Al₂O₃ and 100 Al₂O₃:F ALD cycles. The temperature-independent growth “plateau” occurs over a temperature range of 185° C. to 300° C. and denotes the deposition range where the enthalpy of surface reactions dominates the deposition rate, rather than the substrate thermal energy. Above this range the growth rate becomes an exponential Arrhenius function more typically observed in chemical vapor deposition. To ensure ALD-like growth conditions a substrate temperature of 200° C. was chosen for all of the samples considered in this study.

Physico-Chemical Characterisation of Al₂O₃:F Films

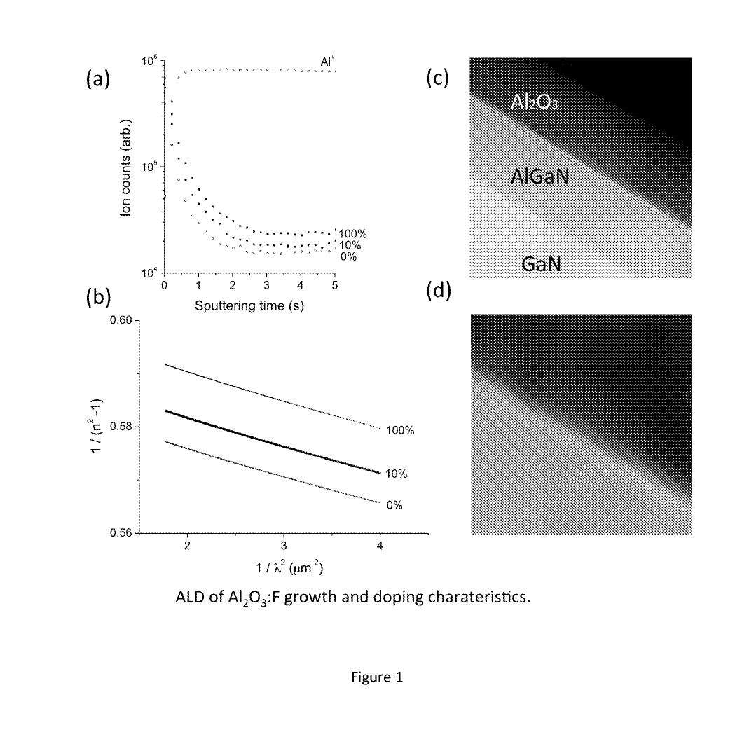

To confirm the presence of fluorine in our samples, secondary ion mass spectrometry was used to provide a depth profile of the fluorine distribution (FIG. 1a) in the 10% and 100% cycle doped films. The distribution of aluminium (Al⁺, mass/charge ratio of m/z 27) initially increases from the surface and stabilizes after is of sputtering time). The other traces (m/z of 19) show a convolution of F⁻ and O¹⁸H⁻ ion distributions. The undoped (0% cycles) film illustrates the background 19 amu distribution, which is predominantly the hydroxyl ion mass interference. For this reason it was not feasible to measure the F-distributions in lower percentage-cycle doped films. The 10% and 100% cycle doped films show an increase in fluorine uptake with doping cycle fraction. Ellipsometry was used to establish the deposition rate (A/cycle) of ALD Al₂O₃ as a function of doping cycles at a growth temperature of 200° C.

Ellipsometry was also used to measure the refractive index dispersion, as it is sensitive to small changes in the chemistry of the films. The effect of the F incorporation can be revealed by measurement of the Sellmeier coefficients, if the overall absorption coefficient k is small [A8]. For the alumina—based films studied here, k˜0 and the refractive index n of the dielectric is given by:

$${n}^{2} ( λ ) = 1 + {\sum }_{j} \frac{{s}_{j} {λ}^{2}}{{λ}^{2} - {λ}_{j}^{2}} \qquad ( 1 )$$

Where Sⱼ is the oscillator strength of an optical transition at wavelength λⱼ and λ is the wavelength of the incident light. Using the single oscillator model, it is assumed that one oscillator dominates, in the wavelength range used (500 nm-800 nm) and a single term Sellmeier relationship can be used:

n²(λ)−1=S₀λ₀²/[1−(λ₀/λ)²] (2)

S₀ effectively represents the average oscillator strength and λ₀ is the average oscillator position. A measurement of the average interband-oscillator energy E₀ (eV) is obtained from E₀=hc/eλ₀, where c is the speed of light, h is Planck's constant and e is the electronic charge. FIG. 1b shows a plot of n²−1 versus 1/λ² for films of undoped alumina and with doping cycle percentages of 10% and 100%. The gradient of the straight line for each sample is a measure of 1/S₀ and the intercept reflects 1/S₀λ₀. Lai et al [A9] have previously correlated S₀ and λ₀ with the concentration of fluorine incorporated into thin Al₂O₃ films either by ¹⁹F⁺ ion implantation, CF₄ plasma treatment or a combination of both. In their study they observe Sₒ increases with increasing fluorine dose rate (5×10¹³ cm⁻² to 2×10¹⁴ cm⁻²) and that λ₀ also increases. For the films deposited using the in situ ALD doping process reported here, the same general trend is observed i.e. that the refractive index n decreases and λ₀ increases with increasing exposure to F-doping cycles. However we note that Sₒ is relatively insensitive to the F dosage in comparison with implanted/diffused material.

Transmission electron micrographs were recorded from cross sections of MOS capacitors (FIGS. 1c and d) fabricated from the Al₂O₃:F films, to ensure the thickness of the dielectric and reveal any interactions between the oxide and GaN substrate or top contact metal.

These data show the controlled introduction of fluorine during the ALD film growth. The [F] incorporation is proportional (SIMS and ellipsometry) to the addition of NH₄F to a fraction of the ALD.

### Example 2—Preparation of Metal-Oxide-Semiconductor (MOS Capacitors) (University of Glasgow Data)

MOS capacitors were made by a process of additive; subtractive; and lithographic steps in a sequence suitable for the fabrication of ohmic and rectifying contacts to the semiconductor and dielectric layers.

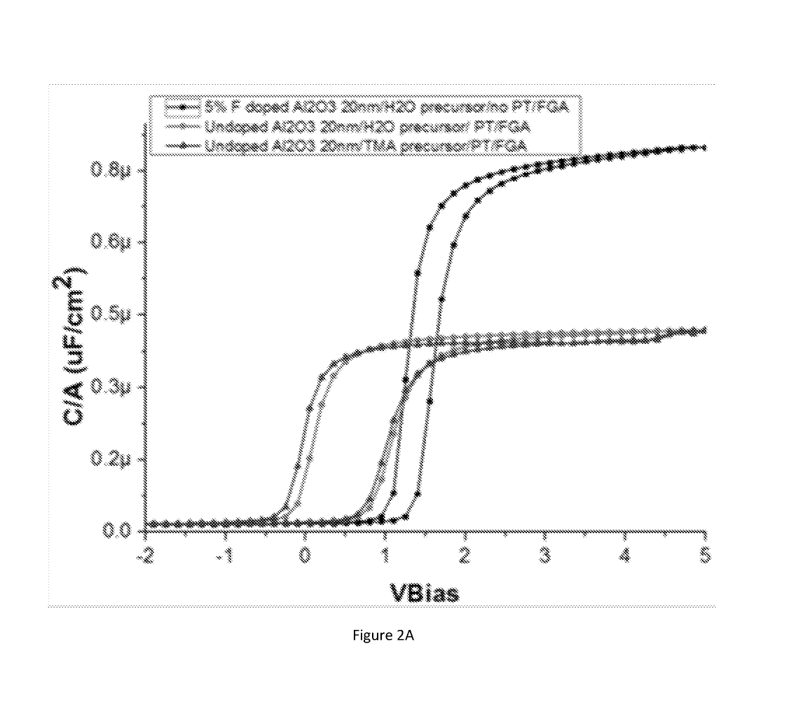

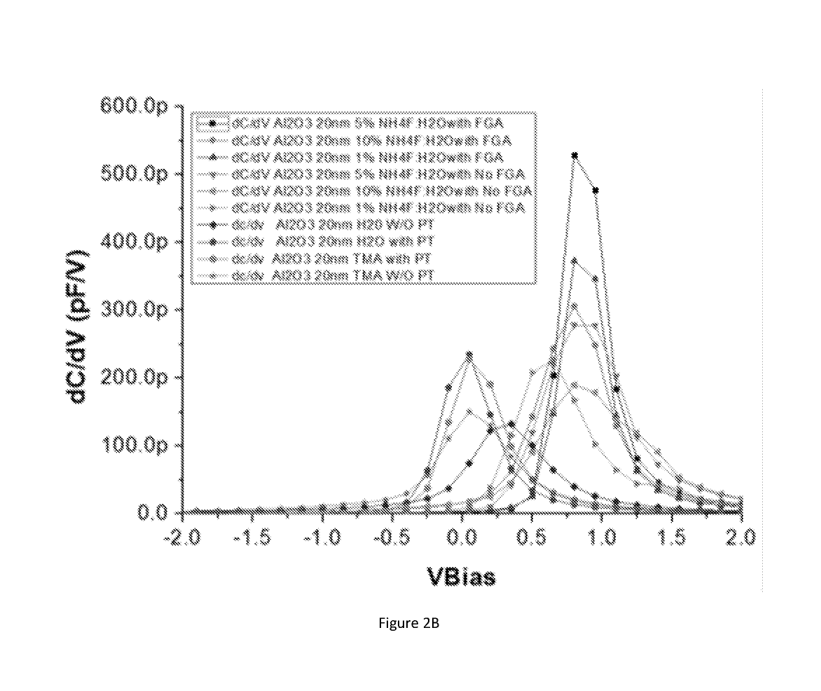

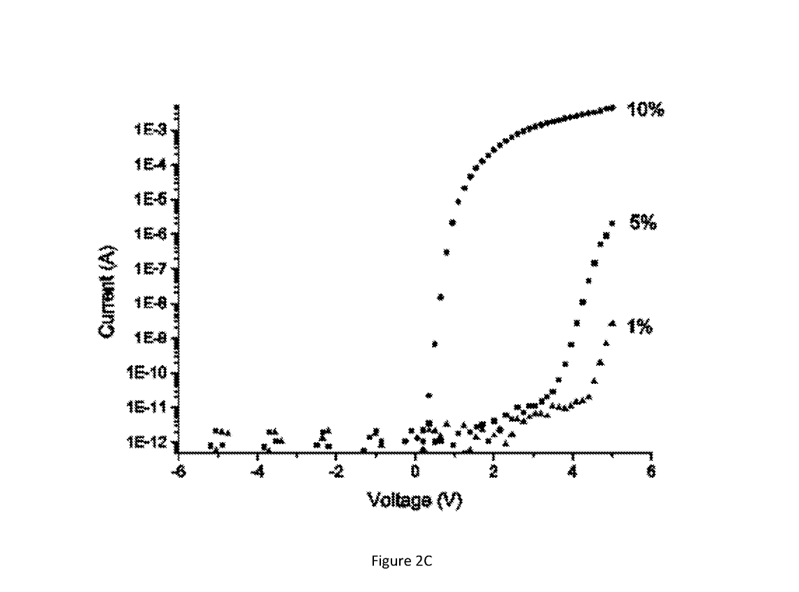

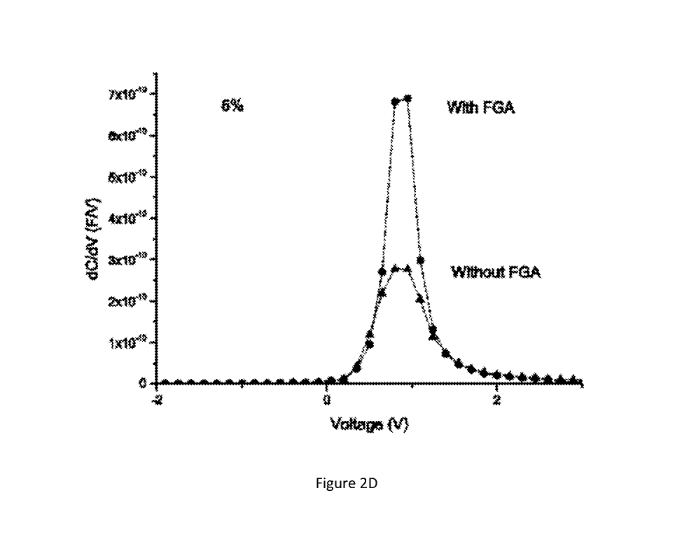

The test results for the capacitors formed with different alumina dielectric barrier layers are shown in FIGS. 2a to 2d.

FIG. 2a shows capacitance-voltage curves, which show F addition shifts the threshold voltage and reduces the hysteresis caused by defects in the oxide.

FIG. 2b shows dC/dV (y-axis) versus V_{Bias} (x-axis) and illustrates that F addition makes a positive threshold voltage.

The leakage current (I-V) data shown in FIG. 2c shows leakage suppression although 10% seems to reinstate leakage again—suggesting upper limit to benefit from doping

All samples benefit from forming gas annealing (FGA) at 430° C. for 30 minutes. FIG. 2d shows the effect of FGA on the performance of a 5% doping cycles, F-doped dielectric layer prepared according the methodology of the present invention.

### Example 3—Metal-Oxide-Semiconductor Field Effect Transistors (MOSFET) (University of Sheffield Data)

MOSFET transistors were prepared by a process of additive; subtractive; and lithographic steps in a sequence suitable for the fabrication of ohmic and rectifying contacts to the semiconductor and dielectric layers.

To compare the effect of fluorine addition, one MOSFET was prepared with a 21.2 nm dielectric barrier layer of alumina doped with fluorine (200 cycles of 1% F-doped doping cycles, Al₂O₃+20 cycles of Al₂O₃) and a second MOSFET was prepared with a 22.2 nm alumina barrier layer (with no fluorine doping).

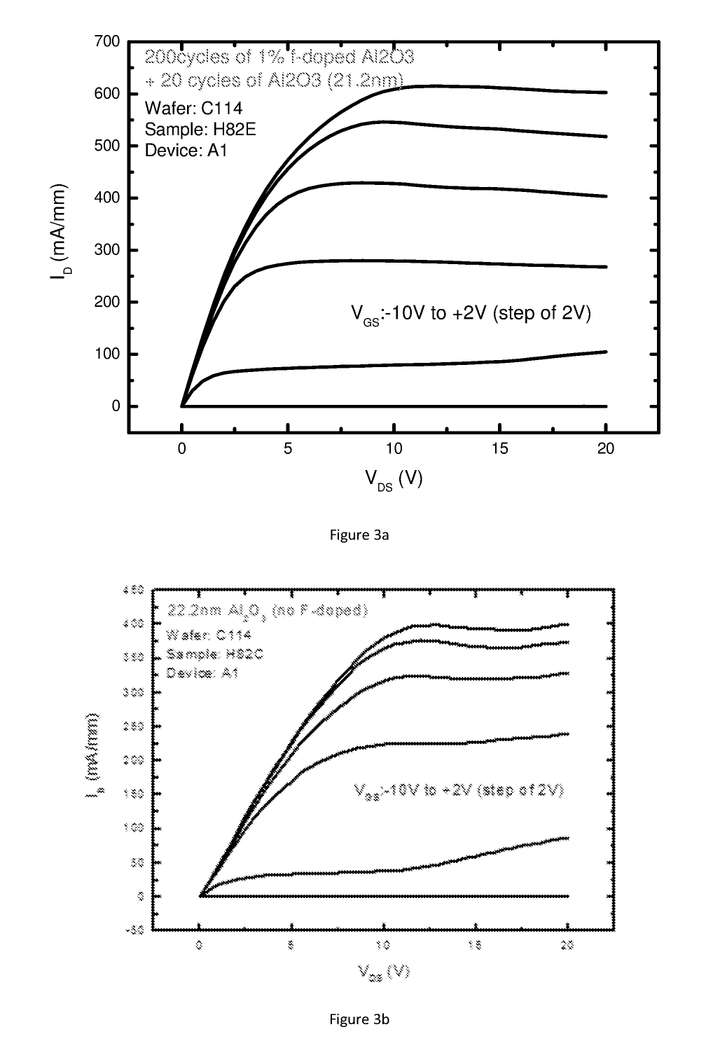

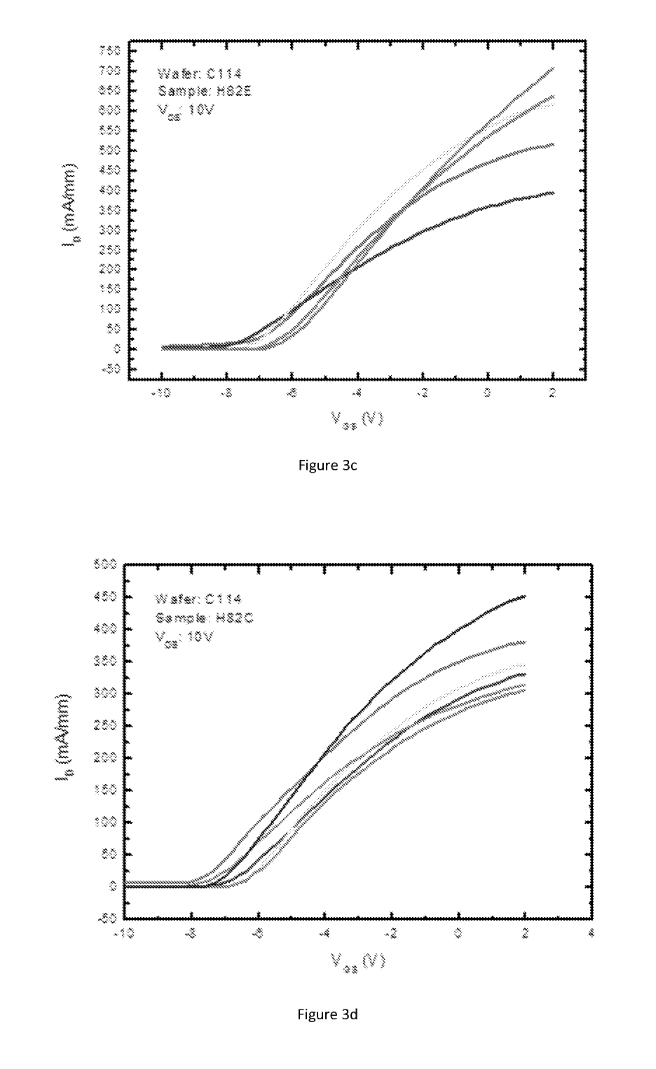

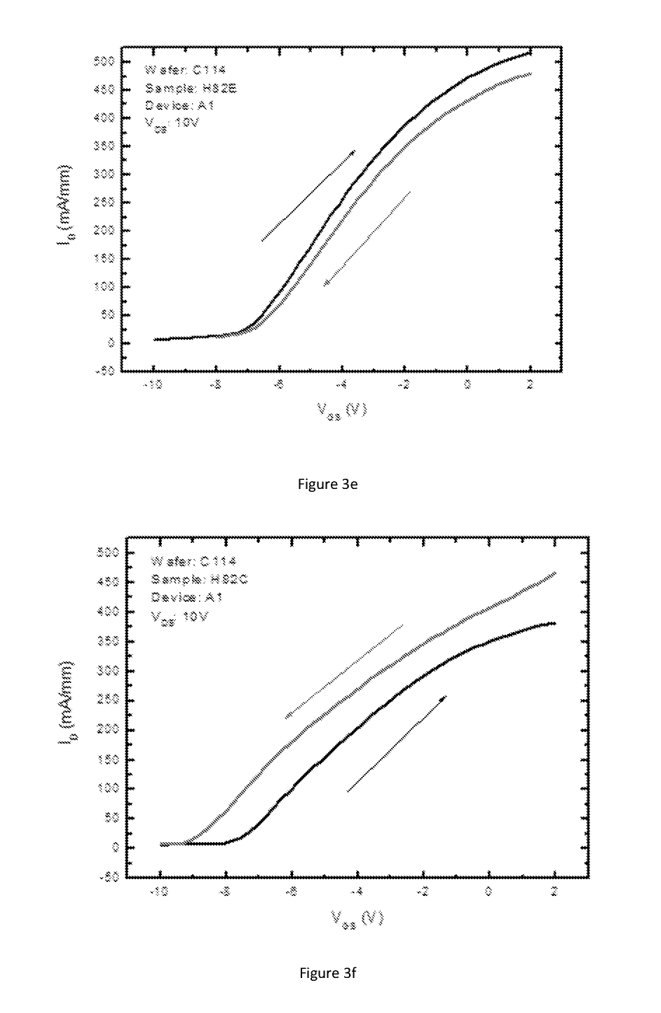

The results are shown in FIGS. 3a to 3f.

MOSFET Prepared with Dielectric Barrier Layer Formed from 200 Cycles of 1% Doping Cycles, F-Doped Al₂O₃+20 Cycles of Al₂O₃ (21.2 nm):
Maximum drain current between 400 and 700 mA/mm

### V_{TH}: ˜−6.5 V to −8 V

Peak gm˜70-100 mS/mm
Hysteresis observed with bi-directional sweeps
MOSFET Prepared with a 22.2 nm Barrier Layer Formed of Al₂O₃ (Non F-Doped):
Maximum drain current between 300 and 450 mA/mm

### V_{TH}: ˜−7 V to −8 V

Peak gm˜55-65 mS/mm
Hysteresis observed with bi-directional sweeps

In summary, fluorine addition in the transistors reduces hysteresis and causes a positive threshold voltage shift.

### REFERENCES

A1. P. D. Ye, B. Yang, K. K. Ng, and J. Bude, “GaN metal-oxide semiconductor high-electron-mobility-transistor with atomic layer deposited Al₂O₃ as gate dielectric,” Appl. Phys. Lett., vol. 86, no. 9, p. 063 501, January 2005.
A2. Y. Z. Yue, Y. Hao, Q. Feng, J. C. Zhang, X. H. Ma, and J. Y. Ni, “GaN MOS-HEMT using ultrathin Al₂O₃ dielectric grown by atomic layer deposition,” Chin. Phys. Lett., vol. 24, no. 8, pp. 2419-2422, August 2007.
A3. Yuanzheng Yue, Yue Hao, Senior Member, IEEE, Jincheng Zhang, Jinyu Ni, Wei Mao, Qian Feng, and Linjie Liu, IEEE Electron Device Letters, vol. 29, NO. 8, AUGUST 2008 p. 838
A4. C. Liu, E. F. Chor, and L. S. Tan, “Investigations of HfO₂/AlGaN/GaN metal-oxide-semiconductor high electron mobility transistors,” Appl. Phys. Lett., vol. 88, no. 9, p. 173 504, April 2006.
A5. Y. Cai, Y. Zhou, K. M. Lau, and K. J. Chen, IEEE Trans. Electron Devices, vol. 53, no. 9, pp. 2207-2215, September 2006.
A6. Chao Chen, Xingzhao Liu, Benlang Tian, Ping Shu, Yuanfu Chen, Wanli Zhang, Hongchuan Jiang, and Yanrong Li, IEEE Electron Device Letters, 32 (10), (2011)
A7. Yuhao Zhang, Min Sun, Sameer J. Joglekar, Tatsuya Fujishima, and Tomas Palacios, Applied Physics Letters 103, O₃3524 (2013)
A8. M. DrDomenico Jr. and S. H. Wemple, Journal of Applied Physics 40, 720 (1969)
A9. Chao Sung Lai, Kung Ming Fan, Hsing Kan Peng, Shian Jyh Lin, Chung Yuan Lee and Chi Fong Ai, Applied Physics Letters 90, 172904 (2007)
A10. R. H. French, D. J. Jones, and S. Loughin, J Amer. Ceram. Soc., 77(2) 412-422 (1994)

1. A method of forming a fluorine-doped metal oxide dielectric layer suitable for forming a dielectric barrier layer in an integrated circuit device, the method comprising the deposition of a plurality of layers of metal oxide dielectric onto a substrate by a plurality of cycles of atomic layer deposition, wherein one or more of said cycles of atomic layer deposition additionally comprises the atomic layer deposition of fluorine.

2. A method according to claim 1, wherein the substrate is a layer of a gallium nitride (GaN) layer, AlN, AlGaN layer, AlInN layer or nitride based alloy in which a two dimensional electron/hole gas can be formed as the channel.

3. A method according to claim 1, wherein the oxide dielectric is selected from alumina (Al₂O₃); hafnia (HfO₂); zirconia (ZrO₂); titania (TiO₂); rare earth element (RE) oxides (RE₂O₃ or REO₂); or a mixture thereof.

4. A method according to claim 3, wherein the oxide dielectric is in a pure state.

5. A method according to claim 3, wherein the oxide dielectric is in a doped state.

6. A method according to claim 3, wherein the oxide dielectric is a ternary or quaternary composition of the metal oxide dielectric, which are either in a pure or doped compositional state.

7. A method according to claim 1, wherein the oxide dielectric is alumina.

8. A method according to claim 7, wherein alumina is deposited by the atomic layer deposition of an aluminium source (e.g. trimethyl aluminium) followed by the either the atomic layer deposition of water vapour, oxygen plasma treatment or ozone treatment.

9. A method according to claim 1, wherein the thickness of the oxide dielectric layer is from 1 nm to 500 nm.

10. A method according to claim 1, wherein the total number of cycles of atomic layer depositions may be within the range of 5 to 100,000 cycles.

11. A method according to claim 10, wherein the total number of cycles of atomic layer depositions may be within the range of 50 to 2000 cycles.

12. A method according to claim 1, wherein fluorine is deposited by introducing a fluorine source between doses of the metal oxide source.

13. A method according to claim 1, wherein fluorine is introduced in one of every 1 to 200 cycles of oxide deposition.

14. A method according to claim 1, wherein fluorine is introduced in a regular manner so as to provide a regular distribution of fluorine throughout the metal oxide dielectric layer.

15. A method according to claim 1, wherein fluorine is introduced in an irregular manner to provide a more varied distribution of fluorine throughout the metal oxide dielectric barrier layer.

16. A method according to claim 1, wherein the fluorine is introduced by the introduction of a fluorine source into the ALD apparatus and said fluorine source is selected from the group consisting of fluorocarbons that are miscible with water or other suitable solvent, xenon fluoride, or an aqueous fluoride solution.

17. A method according to claim 16, wherein the fluoride source is an aqueous solution of ammonium fluoride.

18. A method according to claim 1, wherein fluorine is deposited in the presence of a co-dopant.

19.-23. (canceled)

24. A fluorine-doped metal oxide dielectric barrier layer obtainable by a method according to claim 1.

25. (canceled)

26. An integrated circuit device comprising a fluorine-doped metal oxide dielectric barrier layer according to claim 24.
